(19) United States
(12) Patent Application Publication
(10) Pub. No.: US 2014/0009379 A1
(43) Pub. Date: Jan. 9, 2014

(54) CAVITY LINERS FOR ELECTROMECHANICAL SYSTEMS DEVICES

(71) Applicant: Sandeep K. Giri, San Diego, CA (US)

(72) Inventor: Sandeep K. Giri, San Diego, CA (US)

(73) Assignee: QUALCOMM MEMS TECHNOLOGIES, INC., San Diego, CA (US)

(21) Appl. No.: 13/543,121

(22) Filed: Jul. 6, 2012

(51) Int. Cl. G02B 26/00; G06F 3/01; C23C 16/44; G06F 3/038

(52) U.S. Cl. 345/156; 359/290; 345/204; 427/58

(57) ABSTRACT

This disclosure provides systems, methods and apparatus for electromechanical systems devices with improved electrical properties and device life span. In one aspect, a conformal antistiction layer is formed within a cavity of an electromechanical systems apparatus over a roughened surface. The conformal antistiction layer can include a dielectric layer. The conformal antistiction layer can include a self-assembled monolayer (SAM) formed over the dielectric layer. The conformal antistiction layer can replicate the roughness of the surface that it is deposited on.

### TECHNICAL FIELD

This disclosure relates to coatings for electromechanical systems.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

During operation of the electromechanical systems device the movable electrode repeatedly contacts the stationary electrode. The repeated contact causes wear to the surfaces. The contacting surfaces can sometimes “stick” or become hard to separate from a position where the surfaces are in contact with each other due to physical and electrostatic attraction known in the art as stiction.

### SUMMARY

The systems, methods and devices of the disclosure each have several innovative aspects, no single one of which is solely responsible for the desirable attributes disclosed herein.

One innovative aspect of the subject matter described in this disclosure can be implemented in an electromechanical systems apparatus. In the implementation, the electromechanical systems apparatus includes a first electrode and a second, movable electrode that is separated from the first electrode by a cavity. A surface between one of the electrodes and the cavity is a roughened surface. A conformal antistiction layer formed within the cavity over the roughened surface and over the other of the electrodes.

The conformal antistiction layer can include a material having a hardness greater than a material defining the roughened surface. The roughened surface and the conformal antistiction layer formed thereover can each have a roughness of between about 1.5 nm rms and about 6 nm rms. The conformal antistiction layer can include a dielectric layer that has a conformality such a thinnest portion thereof has a thickness greater than about 90% of a thickest portion thereof. The conformal antistiction layer can include a dielectric material and a self-assembled monolayer. The electromechanical systems apparatus can be an interferometric modulator.

Another innovative aspect can be implemented in a method for manufacturing an electromechanical systems device. The implementation includes forming a first electrode, forming a sacrificial material over the first electrode and forming a second electrode over the sacrificial layer, wherein a roughened surface faces the sacrificial layer between one of the first and second electrodes and the sacrificial layer. The implementation also includes removing the sacrificial layer to form a cavity with opposite sides defined by the first electrode and the second electrode. A conformal layer is deposited in the cavity by atomic layer deposition.

The roughened surface can be provided by forming the sacrificial layer with a roughened template surface and forming the second electrode with the roughened surface over the roughened template surface. Depositing the conformal layer can include replicating the roughened surface to have a roughness greater than about 2 nm rms. Depositing the conformal layer can include depositing a material that is harder than a material defining the roughened surface. Depositing the conformal layer can include depositing a dielectric material. A self-assembled monolayer (SAM) can be formed over the conformal layer.

Another innovative aspect can be implemented in an electromechanical systems device. The implementation includes a first electrode means, a second, movable electrode means and a cavity defined between the first and second electrode means. At least one of the first and second electrode means has a roughened surface facing the cavity. Means for reducing stiction cover surface of the first electrode means and the second electrode means that face the cavity, including over the roughened surface.

The means for reducing stiction can include a conformal dielectric layer, and can further include a self-assembled monolayer formed over the conformal dielectric layer. The conformal dielectric layer can be deposited by ALD and can have a thickness between about 2.5 nm and about 10 nm. The first electrode means can be a stationary electrode.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4A shows an example of a partial cross-section of the interferometric modulator display of FIG. 1.

FIGS. 4B-4E show examples of cross-sections of varying implementations of interferometric modulators.

FIG. 5 shows an example of a flow diagram illustrating a manufacturing process for an interferometric modulator.

FIGS. 6A-6E show examples of cross-sectional schematic illustrations of various stages in a method of making an interferometric modulator.

FIG. 7A shows an example of a cross-sectional schematic illustration of an electromechanical systems device with a conformal antistiction layer.

FIG. 7B shows an example of a cross-sectional schematic illustration of an interferometric modulator having a conformal antistiction layer.

FIG. 7C shows an enlarged section of an example of a portion of the interferometric modulator of FIG. 7B.

FIG. 8 shows an example of a flow diagram illustrating a method for processing electromechanical systems devices.

FIGS. 9A and 9B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, and electronic test equipment. Thus, the teachings are not intended to be limited to the implementations depicted solely in the Figures, but instead have wide applicability as will be readily apparent to a person having ordinary skill in the art.

Processing electromechanical systems devices can include a release etch process to etch a portion of each device to form an internal cavity in the device. After release, a conformal antistiction layer can be formed in the cavity to reduce stiction in the device. The conformal antistiction layer can include a layer formed by atomic layer deposition (ALD). In some implementations, additional deposition of a self-assembled monolayer (SAM) formed on top of the dielectric layer can provide even further antistiction properties over a dielectric layer alone. In some implementations, the antistiction layer can be conformally formed over a roughened surface within the cavity, with a conformality and thickness such that the antistiction coating(s) exhibit a roughness similar to the underlying surface. In some implementations the roughness of the antistiction layer can be varied based on the desired pixel color in the electromechanical systems devices.

Particular implementations of the subject matter described in this disclosure can be implemented to realize one or more of the following potential advantages. The hardness of the conformal antistiction layer and wear-resistance can preserve the roughness of the antistiction layer even after long use of the device. The conformal antistiction layer can also enhance the antistiction properties of the roughness and/or can reduce the degree of roughness employed for a given antistiction effect. The use of a conformal antistiction layer formed over a roughened surface can result in improved electromechanical systems device performance, such as increased lifespan of the device. The use of roughened antistiction layers can increase device resistance to humidity and other contaminants and mitigate surface charging, which can result in improved electrical properties and device performance and stability.

An example of a suitable MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, e.g., by changing the position of the reflector.

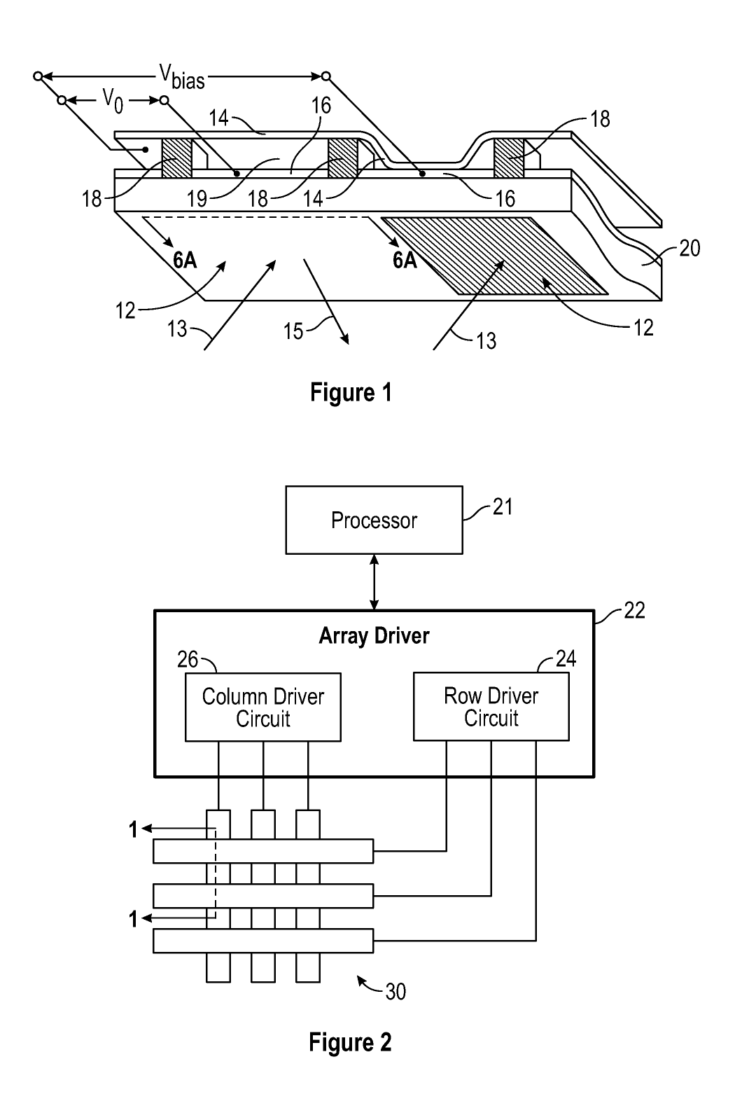

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white. While the description below concerns particularly implementations wherein the open state corresponds to an unactuated device and the closed state corresponds to an actuated device, one having ordinary skill in this art will appreciate that in other implementations electromechanical systems devices can be arranged to be closed in an unactuated state.

The IMOD display device can include a row/column array of IMODs. Each IMOD can include a pair of reflective layers, e.g., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when open, reflecting light within the visible spectrum, and may be in a dark state when collapsed or closed, reflecting light outside of the visible range (e.g., infrared light). In some other implementations, however, an IMOD may be in a dark state when open, and in a reflective state when collapsed or closed. In some implementations, the introduction of an applied voltage can drive the pixels to change states. In some other implementations, an applied charge can drive the pixels to change states.

The depicted portion of the pixel array in FIG. 1 includes two adjacent electromechanical systems devices in the form of interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows indicating light 13 incident upon the pixels 12, and light 15 reflecting from the pixel 12 on the left. Although not illustrated in detail, it will be understood by a person having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12 on the viewing or substrate side of the device.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of supports, such as the illustrated posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

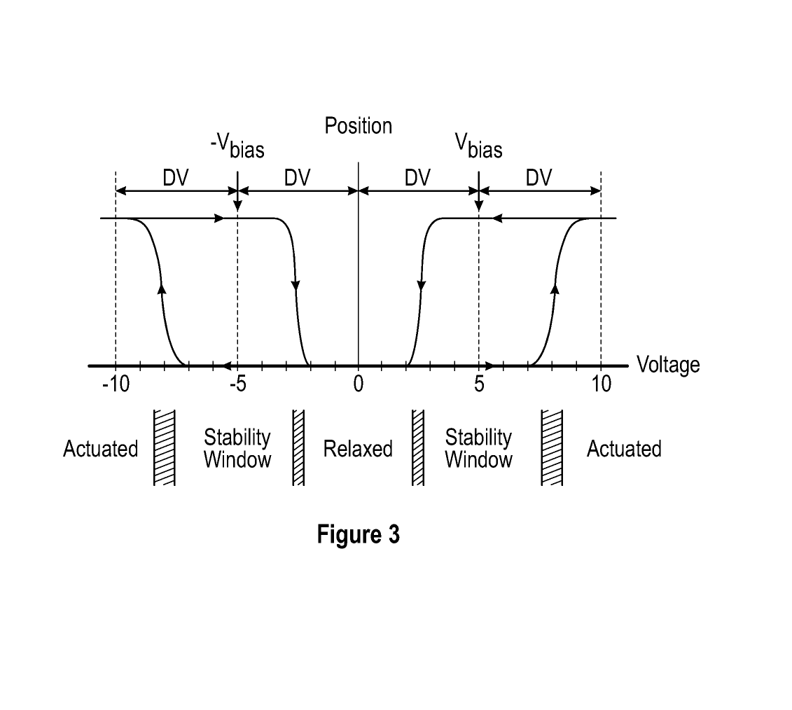

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

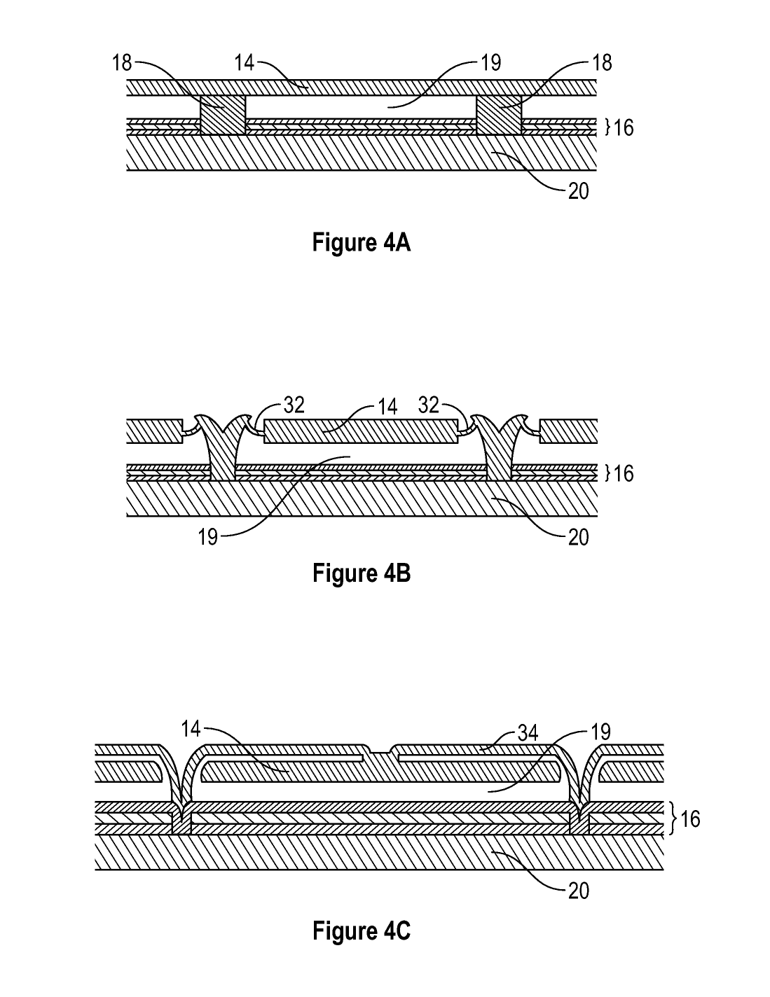

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

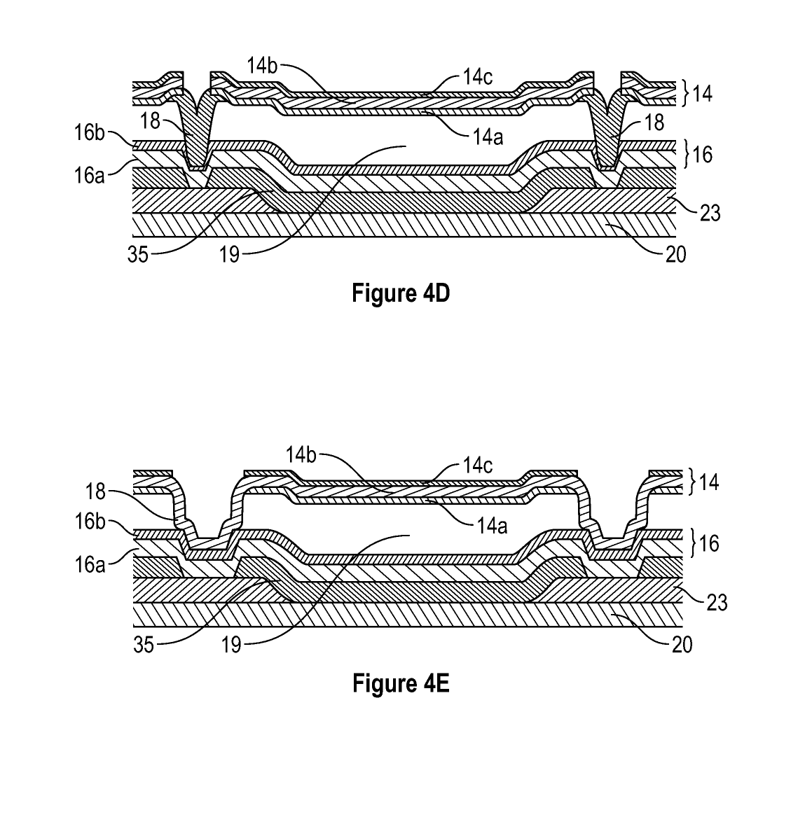

The details of the structure of interferometric modulators that operate in accordance with the principles set forth above may vary widely. For example, FIGS. 4A-4E show examples of cross-sections of varying implementations of interferometric modulators, including the movable reflective layer 14 and its supporting structures.

FIG. 4A shows an example of a partial cross-section of the interferometric modulator display of FIG. 1, where a strip of metal material, i.e., the movable reflective layer 14 is deposited on supports 18 extending orthogonally from the substrate 20. In FIG. 4B, the movable reflective layer 14 of each IMOD is generally square or rectangular in shape and attached to supports at or near the corners, on tethers 32. In FIG. 4C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 4C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 4D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a and 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 4D, some implementations also can include a black mask structure 23. The black mask structure 23 can be formed in optically inactive regions (e.g., between pixels or under the support posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, an optical cavity layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoride (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate electrodes or conductor(s) in the optical stack 16 (e.g., the absorber layer 16a) from the conductive layers in the black mask 23.

FIG. 4E shows another example of an IMOD, where the movable reflective layer 14 is self supporting. In contrast with FIG. 4D, the implementation of FIG. 4E does not include separately formed support posts. Instead, the movable reflective layer 14 contacts the underlying optical stack 16 at multiple locations to create integrated supports 18, and the curvature of the movable reflective layer 14 that provides sufficient support that the movable reflective layer 14 returns to the unactuated position of FIG. 4E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed or stationary electrode and as a partially reflective layer.

In implementations such as those shown in FIGS. 4A-4E, the IMODs function as direct-view devices, in which images are viewed from the front side of the transparent substrate 20, i.e., the side opposite to that upon which the modulator is formed. In these implementations, the back portions of the device (that is, any portion of the display device behind the movable reflective layer 14, including, for example, the deformable layer 34 illustrated in FIG. 4C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 4A-4E can simplify processing, such as, e.g., patterning.

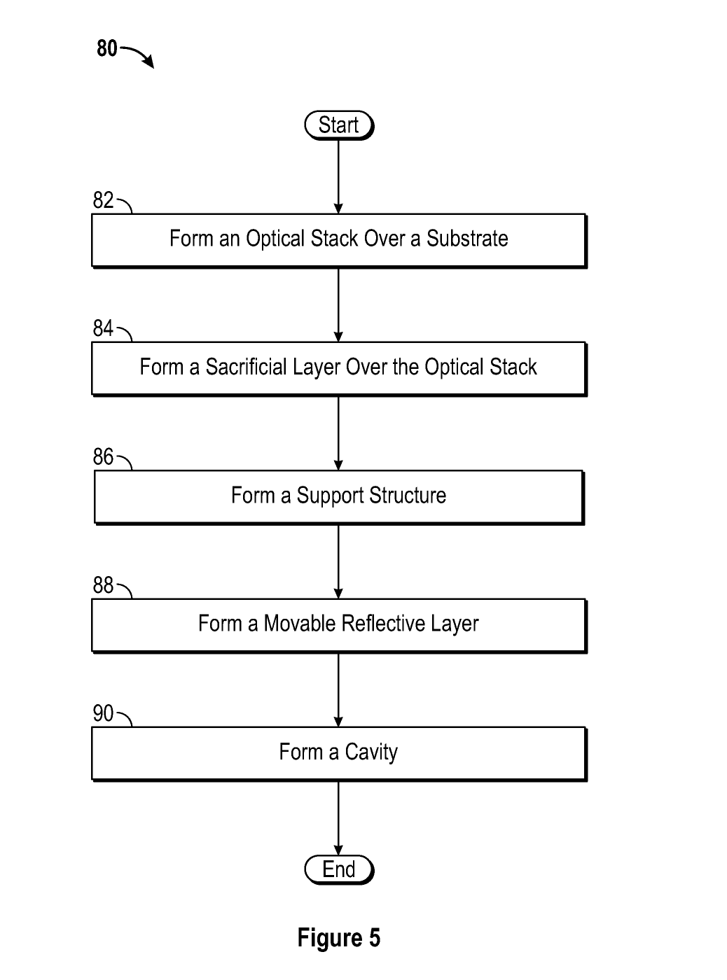

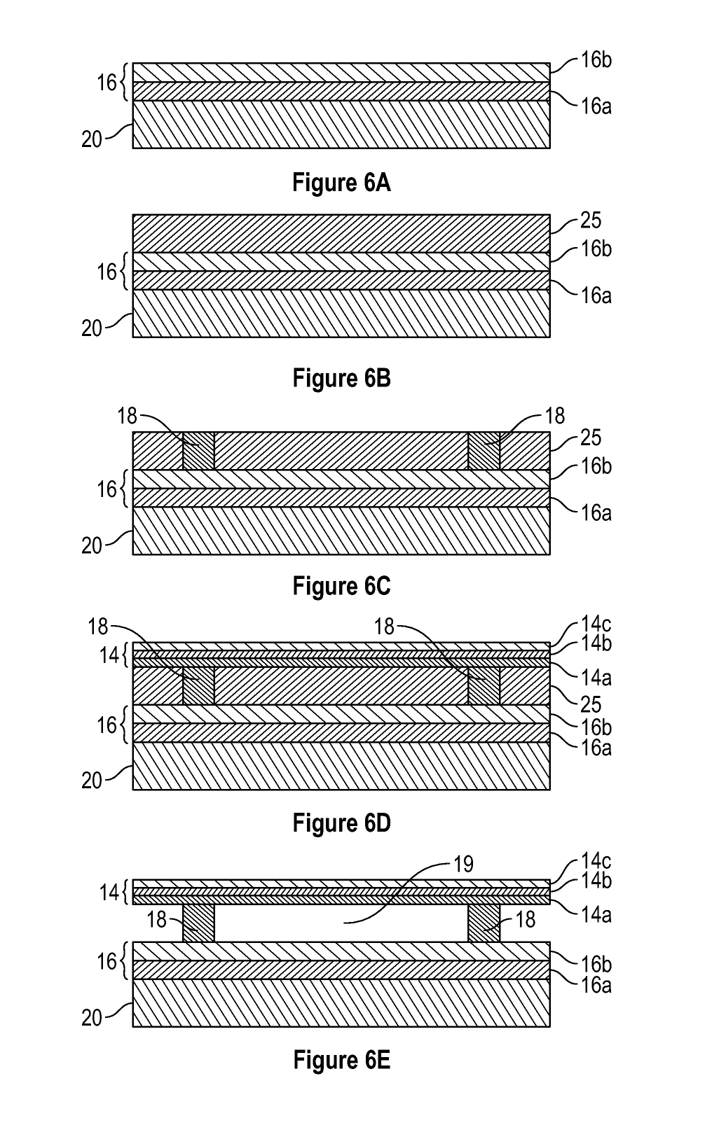

FIG. 5 shows an example of a flow diagram illustrating a manufacturing process 80 for an interferometric modulator, and FIGS. 6A-6E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 4A-4E, in addition to other blocks not shown in FIG. 5. With reference to FIGS. 1, 4A-4E and 5, the process 80 begins at block 82 with the formation of the optical stack 16 over the substrate 20. FIG. 6A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 6A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators illustrated in FIGS. 1 and 4A-4E. FIG. 6B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (a-Si), in a thickness selected to provide, after subsequent removal, a gap or cavity 19 (see also FIGS. 1, 4A-4E And 6E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 4A, 4D and 6C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 4A. Alternatively, as depicted in FIG. 6C, the aperture formed in the sacrificial layer 25 can extend through the sacrificial layer 25, but not through the optical stack 16. For example, FIG. 6E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 6C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 4A-4E and 6D. The movable reflective layer 14 may be formed by employing one or more deposition steps, e.g., reflective layer (e.g., aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, and 14c as shown in FIG. 6D. In some implementations, one or more of the sub-layers, such as sub-layers 14a and 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 4A-4E and 6E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

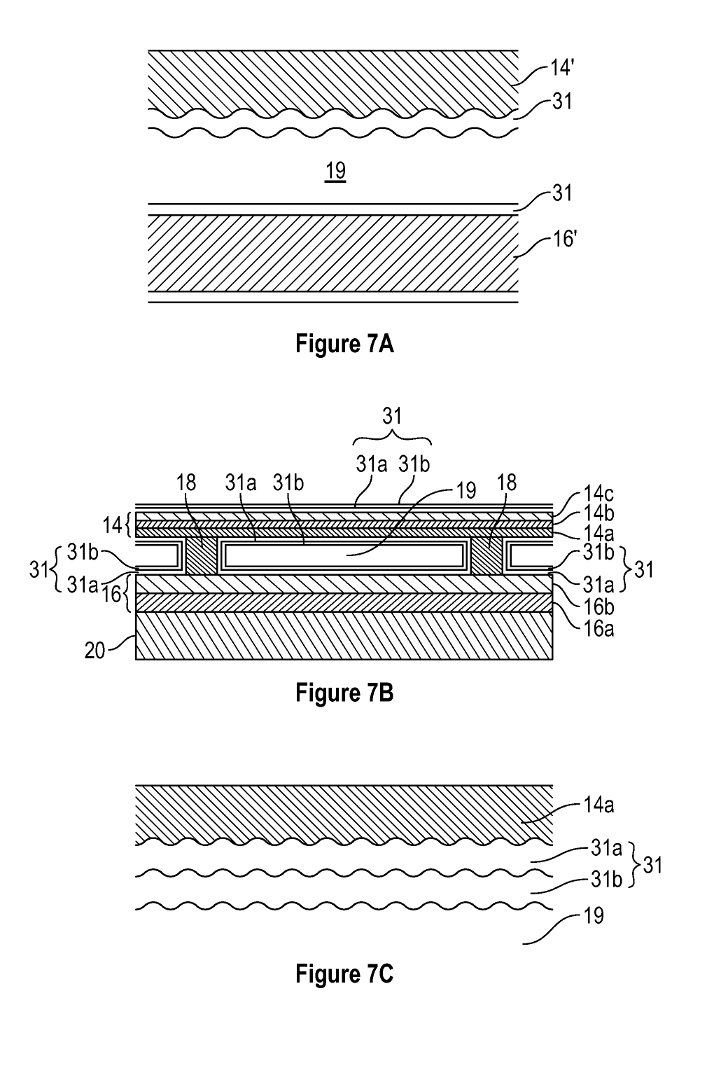

FIG. 7A shows an example of a cross-sectional schematic illustration of an electromechanical systems device with a conformal antistiction layer 31. In one implementation, the electromechanical systems device includes a first electrode 14′ and a second electrode 16′ that is separated from the first electrode 14′ by a cavity 19. At least one of the electrodes 14′ and 16′ is movable. In the one implementation, the first electrode 14′ is movable and the second electrode 16′ is stationary. A surface facing the cavity 19 has a roughed surface. In the illustrated implementation, the first electrode 14′ has a roughened surface; in other implementations, the second electrode 16′ or both the first electrode 14′ and the second electrode 16′ can have roughened surface(s). The conformal antistiction layer 31 is formed within the cavity, over both the roughened surface and the other electrode. In one implementation, the conformal antistiction layer 31 includes an atomic layer deposition (ALD) layer and a self-assembled monolayer (SAM). While not shown in FIG. 7A, in another implementation the conformal antistiction layer can also be formed on an outside surface of the device, such as the surface of the first electrode 14′ facing away from the cavity 19.

FIG. 7B shows an example of a cross-sectional schematic illustration of an interferometric modulator having a conformal antistiction layer. As shown in FIG. 7B, after release etching defines the cavity, at least the reflective layer 14a and top of the optical stack 16, and in the illustrated implementation all interior surfaces of the cavity 19, can be coated conformally with an antistiction layer 31. The illustrated conformal antistiction layer 31 includes a conformal layer 31a, which can be formed by atomic layer deposition (ALD), and a self-assembled monolayer (SAM) 31b as described below. In some implementations the conformal layer 31a can be an inorganic layer. In some implementations the conformal layer 31a can be a dielectric layer. It will be understood that antistiction properties can be obtained with one or both of the conformal layer 31a and the SAM 31b. For implementations in which both are employed, the conformal layer 31a can serve as a seed layer for forming the SAM thereover.

SAMs can be formed in a variety of manners. In one implementation, the SAM layer 31b is formed over the conformal layer 31a in a gas phase deposition process. In one implementation the gas phase deposition includes a catalyst to promote surface reactions of the SAM precursors with the cavity surfaces and/or chain cross-linking. In other gas phase deposition processes, no catalysts are used. In an implementation, the precursor gases are delivered in a static mode, whereby the substrate is placed in a chamber that is backfilled with monomer precursor until the substrate surfaces of interest are saturated and the SAM layer 31b is densely formed. In another implementation, gas phase delivery of the SAMS precursors, with or without catalysts, can be provided in a continuous flow through a reaction chamber housing the substrate. In other implementations, precursors for the SAM layer can be delivered in liquid phase.

In some implementations an electromechanical systems apparatus is provided with a stationary electrode and a movable electrode separated from the stationary electrode by a collapsible cavity. For example, in the implementation illustrated in FIG. 7B, the stationary electrode can be the optical stack 16 and the movable electrode can be the movable reflective layer 14 with the cavity 19 between them. A surface between one of the electrodes and the cavity 19 can be a roughened surface, for example in the implementation illustrated in FIG. 7B the surface of dielectric 16b contacting conformal layer 31a or the surface of reflective layer 14a contacting the conformal layer 31a. An antistiction layer 31 in FIG. 7B, can be formed within the cavity 19 over the roughened surface and over the other of the electrodes (e.g., either of the reflective layer 14a or optical stack 16). In some implementations the antistiction layer 31 includes a conformal dielectric material, such as the conformal layer 31a. The antistiction layer 31 can also include a SAM layer 31b. Both the conformal layer 31a and the SAM layer 31b can be conformally formed, by ALD and self-assembly, respectively. The antistiction layer 31 can also form on external surfaces of the electromechanical systems device, such as the surface of the movable electrode that faces away from the cavity 19, as shown.

FIG. 7C shows an enlarged section of an example of a cross-sectional schematic illustration of a portion of the interferometric modulator of FIG. 7B. FIG. 7C shows the reflective layer 14a with a roughened surface. The conformal antistiction layer 31 is formed over the roughened surface of the reflective layer 14a and has a similar roughness to the underlying surface of the reflective layer 14a. In the illustrated implementation, the antistiction layer includes a conformal layer 31a and an additional SAM layer 31b that is also conformal and so also replicates the surface roughness provided by the reflective layer 14a. Additionally, the antistiction layer 31 could alternatively or additionally coat a rough surface on the optical stack 16 (or on the stationary electrode for EMS more generally) on the opposite side of the gap. Techniques for roughened surfaces bordering the cavity, under the antistiction layer 31, and degrees of roughness are described below.

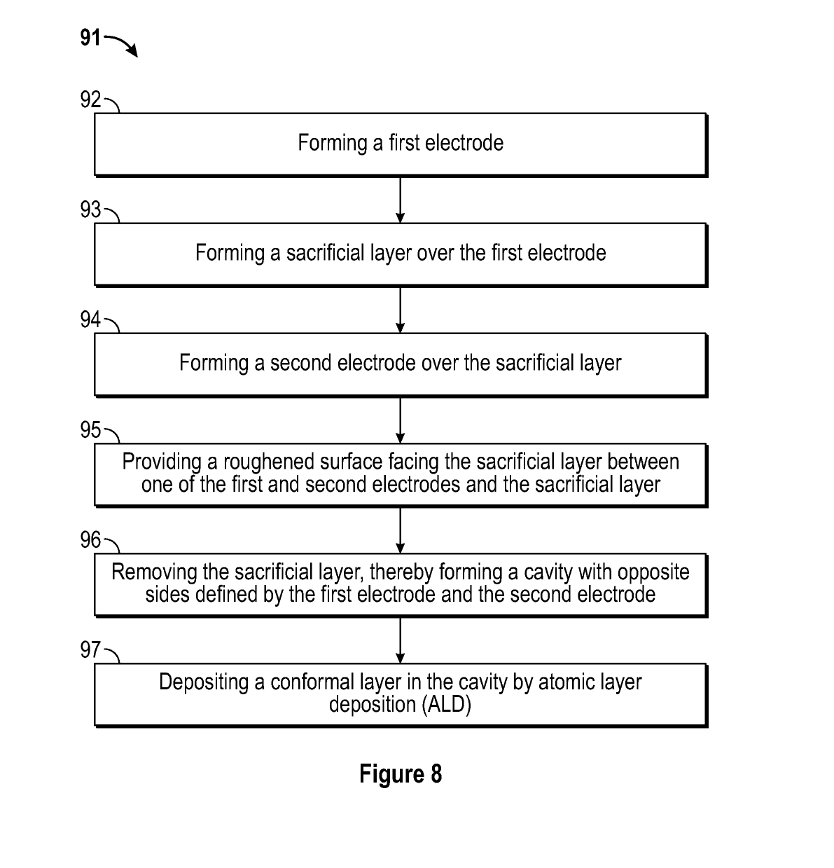

FIG. 8 shows an example of a flow diagram illustrating a method 91 for manufacturing an electromechanical systems device. The method 91 need not be conducted in the illustrated sequence. In some implementations the method 91 includes at block 92 forming a first electrode. At block 93, a sacrificial layer is formed over the first electrode. In some implementations the sacrificial layer can be formed with one or more roughened surfaces. At block 94, a second electrode is formed over the sacrificial layer. At block 95, a roughened surface is provided facing the sacrificial layer between one of the first and second electrodes and the sacrificial layer. The roughened surface can be provided either on the first electrode side of the sacrificial layer or the second electrode side of the sacrificial layer. At block 96, the sacrificial layer is removed thereby forming a cavity with opposite sides defined by the first electrode and the second electrode. At block 97, a conformal layer is deposited in the cavity by atomic layer deposition (ALD). In some implementations a self-assembled monolayer (SAM) can be formed on top of the conformal layer deposited by ALD.

In some implementations the electromechanical systems device is an interferometric modulator.

As noted above, FIG. 7A shows an example of an IMOD having the cavity 19 with the conformal layer 31a and the SAM layer 31b formed within the cavity 19. The vapor phase deposition reactants can reach the interior surfaces of the cavity 19 by the same paths that the release etch vapors follow, such as etch holes (not shown) in the reflective movable layer 14, gaps between adjacent strips of the reflective movable layer 14 in an array, and laterally between supports 18. Although not illustrated, one having ordinary skill in the art will recognize that the dielectric layer and/or SAM depositions can also leave dielectric and SAM layers on outer surfaces of the device, such as the upper surface of the conductive layer 14c.

In some implementations the movable electrode has a first surface facing the cavity and a second surface on the other side of movable electrode opposing the first surface. In some implementations the conformal antistiction layer is formed over the first and second surfaces of the movable electrode.

In some implementations the antistiction layer 31 includes a dielectric material as the conformal layer 31a, such as one or more of aluminum oxide (Al₂O₃), hafnium oxide (HfO₂), tantalum oxide (Ta₂O₅), and silicon dioxide (SiO₂). In some implementations the conformal layer 31a is Al₂O₃. The antistiction layer 31 can be formed by ALD or CVD. The conformal layer 31a can be formed by providing a reactant including aluminum, hafnium, tantalum or silicon along with an oxidizing agent. The deposition chamber can be pumped down and/or purged between reactant pulses to keep the mutually reactive reactants separated. For example, a metal precursor can self-limitingly adsorb a monolayer or less in one pulse; excess metal precursor is removed from the deposition chamber, such as by purging; an oxidizing agent reacts with the adsorbed species of the metal precursor; and excess oxidizing agent is removed from the deposition chamber before the next precursor. Each cycle leaves no more than about one monolayer of metal oxide in this example. More complex sequences can be provided, especially for more complex materials. For example, aluminum oxide can be formed by ALD processes using alternate and sequential pulses of trimethyl aluminum (TMA, (CH₃)₃Al) and an oxygen source vapor, such as water. The alternate and sequential pulses can be repeated until an aluminum oxide film having a desired thickness is deposited. In some implementations the reaction space has a temperature of less than about 100° C. during the alternate and sequential pulses of the ALD process.

Hafnium oxide can be formed by alternately and sequentially providing a hafnium halide or hafnium organic compound and an oxidizing agent, such as water. Tantalum oxide can be formed by alternately and sequentially providing a tantalum halide or tantalum organic compound and an oxidizing agent, such as water.

In some implementations the conformal antistiction 31 layer has a thickness of greater than about 2.5 nm or 3.0 nm. The thickness of the antistiction layer 31 can include the thickness of the dielectric material or conformal layer 31a by itself or the thickness of the material 31a and any SAM 31b formed on top of the conformal layer 31a. In some implementations the thickness of the antistiction layer is from about 2.5 or 3.0 nm to about 10 nm. In some implementations the thickness of the antistiction layer is from about 2.5 or 3.0 nm to about 10 nm. In some implementations the thickness of the conformal layer 31a is greater than about 2.5 nm. In some implementations the thickness of conformal layer 31a is from about 40 angstroms to about 60 angstroms. In some implementations the thickness of conformal layer 31a is about 90 angstroms or less.

Thicknesses of less than about 100 angstroms for the conformal antistiction layer may not affect the optical properties of the electromechanical device or involve modifying the thickness of the optical stack. Thicknesses of about 100 angstroms to 200 angstroms for the conformal antistiction layer may affect the optical properties of the electromechanical device. The thickness of the optical stack or other properties of the electromechanical systems device can be modified to account for any changes in the optical or mechanical properties of the device resulting from a thick antistiction layer.

In some implementations conformal layer 31a is formed by ALD to a thickness of greater than about 2.5 nm or 3.0 nm. In some implementations about 25 to about 30 or more ALD cycles are used to obtain a thickness of 2.5 to 3.0 nm. In some implementations about 80-100 ALD cycles are used to obtain a thickness of about 8.0-10.0 nm. In some implementations the thickness of the SAM 31b formed on the conformal layer 31a is between about 7 Å and 35 Å, and can be greater than about 1.0 nm.

In some implementations the antistiction layer 31 can be deposited over the surfaces within the cavity 19, including the stationary electrode (e.g. part of 16) and movable electrode (e.g. part of 14). The antistiction layer can be deposited with a high conformality. For example, the conformal 31a can have a conformality such that a thinnest portion thereof has a thickness greater than about 90% of a thickest portion.

In some implementations the antistiction layer 31 includes a material having a greater hardness than a material defining the roughened surface. In some implementations the roughened surface under the antistiction layer 31 can be a reflective material, such as aluminum or an aluminum alloy. In some implementations the antistiction layer 31 has a hardness that is greater than the hardness of an aluminum alloy, e.g. AlCu. In some implementations the conformal layer 31a has a Young's modulus in the range of about 160 GPa to 190 GPa, a Berkovitch hardness of about 10 GPa to 14 GPa, a universal hardness between about 7 GPa and 9 GPa and/or an intrinsic in-plane stress in the range of about 350 MPa to 500 MPa.

In some implementations the antistiction layer 31 can include a conformal layer 31a along with a SAM 31b formed on the conformal layer 31a. In some implementations the conformal layer 31a can be used as a seed layer to facilitate the deposition of a SAM 31b within the cavity 19 on the conformal layer 31a. The self-assembled monolayer (SAM) 31b can be exposed to the interior of the cavity 19. The SAM 31b can be formed of monomers that are typically organic chain molecules that have a hydrophilic end in contact with the dielectric material along with an opposing hydrophobic end facing the interior of the cavity 19.

In some implementations the SAM 31b is formed using n-decyl-trichlorosilane as a reactant. For example n-decyl-trichlorosilane can be provided to the electromechanical systems device in liquid or vapor form such that the reactant contacts the conformal layer 31a. The conformal layer 31a can have a surface termination including hydroxyl (—OH) groups. The SAM reactant can react with the hydroxyl groups on the surface of the conformal layer 31a. In some implementations the reaction space has a temperature of less than about 50° C. during the deposition of the SAM. In some implementations the SAM reactant is provided to the electromechanical systems device and allowed to soak the reaction space. In some implementations multiple pulses of the SAM reactant are provided to the reaction space. In some implementations the SAM 31b can be formed using octadecyl trichlorosilane, pentadecyl trichlorosilane, or dodecyl trichlorosilane.

In some implementations depositing the conformal layer 31a and forming the SAM 31b are conducted in-situ in a same deposition chamber. In some implementations the conformal layer 31a can be deposited in one reaction space of a cluster tool and the SAM 31b can be deposited in another reaction space in the cluster tool. In some implementations there is no vacuum break between depositing the conformal layer 31a and the SAM 31b to minimize contamination. In some implementations there is a vacuum break between depositing the conformal layer 31a and the SAM 31b.

In some implementations the antistiction layer 31 or conformal layer 31a is deposited over a roughened surface. The roughened surface can be defined by the antistiction layer 31 between the stationary electrode and the cavity. The conformal layer 31 can be deposited over the roughened surface to leave a coating surface with a roughness similar to the roughness of the underlying layer. The roughened surface can be formed in a variety of ways. The antistiction layer 31 can preserve the surface morphology of any underlying material.

In some implementations providing the roughened surface includes forming the sacrificial layer with a roughened template surface and forming the movable reflective layer with the roughened surface over the roughened template surface. The sacrificial layer can be deposited using deposition conditions (e.g. temperature, reactant flow rate, deposition rate, etc.) that result in a particular roughness on a surface of the sacrificial layer. In some implementations, the sacrificial layer can be roughened after deposition by a treatment, such as ion bombardment of controlled power and duration.

In some implementations the sacrificial layer or stationary electrode can be patterned to have bumps or a roughened surface. Photolithography can be used to pattern the stationary electrode or surface of the sacrificial layer. A mask layer with areas having different etch rates for a given etchant can be used to form the roughened surface or template for the roughened surface. In some implementations patterning may include electron beam lithography and/or image transfer. In some implementations patterning can include the use of a positive or negative photoresist).

In some implementations bumps on the roughened surface can be obtained by various deposition techniques. For example, flash deposition, short term sputtering, applying nanotubes or other random nano-type objects (e.g., by spin coating of a solution that comprises nanotubes), and/or aluminum deposition/anodization may be used.

In some implementations nanoparticles can be used on the top of the stationary electrode or on top of the sacrificial layer. The size of the particles can be selected based on the desired roughness of the surface. In some implementations oxide nanoparticles can be used. In some implementations aluminum oxide nanoparticles may be used. In some implementations depositing the nanoparticles may include using a spin-on process using a liquid dispersion.

In some implementations a porous surface can be formed to provide the roughened surface or to provide the template for the roughened surface. Either or both of the stationary electrode and movable electrode can include a porous surface. In some implementations the porous surface can be formed by anodizing aluminum to form aluminum oxide.

The sacrificial layer can have a rough surface as deposited and/or the sacrificial layer can have a surface treatment to roughen its surface. In some implementations the surface under the sacrificial layer can be roughened with the sacrificial layer replicating a roughness from an underlying layer. In some implementations particles can be deposited on top of a smooth sacrificial layer. In the implementation illustrated in FIG. 6C, the movable reflective layer 14a can be deposited over the roughened sacrificial layer 25. After the sacrificial layer 25 is removed the roughened surface of the movable reflective layer 14a is exposed to the cavity 19. The conformal layer 31a can be deposited over the roughened surface of the movable reflective layer 14a to leave a coating surface with a roughness that is substantially the same as the roughness of the surface of the movable reflective layer 14a.

In some implementations a surface of the movable layer facing the cavity can be roughened.

In some implementations a surface of the stationary electrode facing the cavity can be roughened.

In some implementations the dielectric layer 16b can have a roughened surface. The surface of the dielectric layer 16b or stationary electrode can be roughened as deposited or can be deposited and then undergo a surface treatment to roughen the surface. After the sacrificial layer 25 is removed the roughened surface of the dielectric layer 16b is exposed to the cavity 19. The conformal layer 31a can then be deposited on the roughened surface of the dielectric layer 16b to leave a surface of the conformal layer 31a with a roughness similar to the roughness similar to the dielectric layer 16b.

In implementations where a SAM 31b is formed over the conformal layer 31a, the roughness of the SAM layer 31b can be substantially similar to the roughness exhibited by the surface of the underlying conformal layer 31a.

The roughness of the roughened surface can vary. In some implementations the roughened surface and the antistiction layer 31 formed thereover can each have a roughness of greater than about 1.5 nm root mean square (rms). In some implementations the roughened surface and the surface of the antistiction layer 31 formed thereover can each have a roughness of between about 1.5 nm rms and about 6 nm rms. In some implementations depositing the antistiction layer 31 includes replicating the roughened surface to have a roughness of greater than about 2 nm rms.

In some implementations the roughness of the antistiction layer 31 can be deposited based on the gap size (e.g. distance between the opposing electrode surfaces within the cavity 19 in the open state) or desired color of the resulting pixel. In some implementations for a red pixel the roughness of the antistiction layer 31 can be about 1.5 nm to about 4.0 nm. In some implementations for a green pixel the roughness of the conformal antistiction layer can be about 3.0 nm to about 5.0 nm. In some implementations for a blue pixel the roughness of the antistiction layer 31 can be about 3.0 nm to about 6.0 nm. In some implementations a different roughness is used for each different pixel color. The roughness of the pixel can vary based on the gap size of the pixel. Each gap size can be defined by a separately formed sacrificial layer so the roughness for each gap size can be separately addressed across the array.

In some implementations an electromechanical systems device is provided. The electromechanical systems device can include a stationary electrode means, a movable electrode means for actuating the device, and a cavity defined between the stationary electrode means and the movable electrode means. At least one of the stationary electrode and the movable electrode can have a roughened surface facing the cavity. A means for reducing stiction can be used covering surfaces of the stationary electrode means and the movable electrode means that face the cavity including over the roughened surface.

In some implementations the means for reducing stiction includes a conformal dielectric layer. The conformal dielectric layer can include one or more of Al₂O₃, HfO₂, Ta₂O₅, SiO₂. The conformal dielectric layer can be deposited by ALD and can have a thickness of about 2.5 nm to about 10 nm. In some implementations the means for reducing stiction can also include a self-assembled monolayer (SAM) formed over the conformal dielectric layer. In some implementations the roughened surface is defined by the conformal dielectric layer between the stationary electrode means and the cavity.

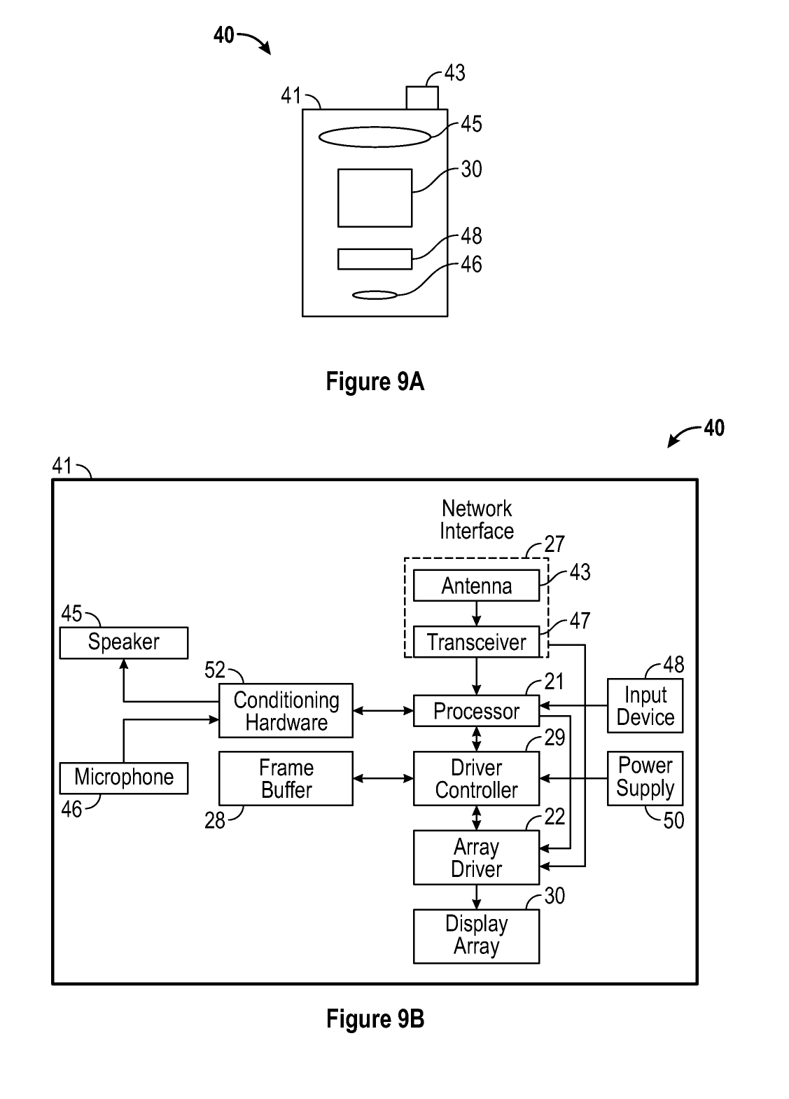

FIGS. 9A and 9B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 9B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), NEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

I claim:

1. An electromechanical systems apparatus comprising:
a first electrode;
a second, movable electrode separated from the first electrode by a cavity, wherein a surface between one of the electrodes and the cavity is a roughened surface; and
a conformal antistiction layer formed within the cavity over the roughened surface and over the other of the electrodes.

2. The apparatus of claim 1, wherein the conformal antistiction layer includes a material having a greater hardness than a material defining the roughened surface.

3. The apparatus of claim 1, wherein the roughened surface and the conformal antistiction layer formed thereover each have a roughness of greater than about 1.5 nm rms.

4. The apparatus of claim 1, wherein the roughened surface and the conformal antistiction layer formed thereover each have a roughness of between about 1.5 nm rms and about 6 nm rms.

5. The apparatus of claim 1, wherein the first electrode is a stationary electrode.

6. The apparatus of claim 1, wherein the conformal antistiction layer includes a dielectric material, wherein the dielectric material has a conformality such that a thinnest portion thereof has a thickness greater than about 90% of a thickest portion.

7. The apparatus of claim 1, wherein the conformal antistiction layer has a thickness of about 2.5 nm to about 10 nm.

8. The apparatus of claim 1, wherein the conformal antistiction layer includes one or more of Al₂O₃, HfO₂, Ta₂O₅, SiO₂.

9. The apparatus of claim 1, wherein the conformal antistiction layer includes a dielectric material and a self-assembled monolayer (SAM).

10. The apparatus of claim 9, wherein the SAM is formed by n-decyl-trichlorosilane.

11. The apparatus of claim 1, wherein the dielectric layer has a universal hardness of between about 7 GPa and 9 GPa.

12. The apparatus of claim 1, wherein the movable electrode has a first surface facing the cavity and a second surface on the other side of movable electrode opposing the first surface, wherein the conformal antistiction layer is formed over the second surface of the movable electrode.

13. The apparatus of claim 1, wherein the electromechanical systems apparatus is an interferometric modulator.

14. A display apparatus including:
the interferometric modulator of claim 13;
a display;
a processor that is configured to communicate with the display, the processor being configured to process image data; and
a memory device that is configured to communicate with the processor.

15. The display apparatus as recited in claim 14, further including:
a driver circuit configured to send at least one signal to the display.

16. The display apparatus as recited in claim 15, further including:
a controller configured to send at least a portion of the image data to the driver circuit.

17. The display apparatus as recited in claim 14, further including:
an image source module configured to send the image data to the processor.

18. The display apparatus as recited in claim 17, wherein the image source module includes at least one of a receiver, transceiver, and transmitter.

19. The display apparatus as recited in claim 14, further including:
an input device configured to receive input data and to communicate the input data to the processor.

20. A method for manufacturing an electromechanical systems device comprising:
forming a first electrode;
forming a sacrificial layer over the first electrode;
forming a second electrode over the sacrificial layer, wherein a roughened surface faces facing the sacrificial layer between one of the first and second electrodes and the sacrificial layer;
removing the sacrificial layer, thereby forming a cavity with opposite sides defined by the first electrode and the second electrode; and
depositing a conformal layer in the cavity by atomic layer deposition (ALD).

21. The method of claim 20, wherein providing the roughened surface includes forming the sacrificial layer with a roughened template surface, and forming the second electrode with the roughened surface over the roughened template surface.

22. The method of claim 20, wherein forming the sacrificial layer with a roughened template surface includes depositing the sacrificial layer under conditions to deposit the sacrificial with the roughened surface.

23. The method of claim 20, wherein forming the sacrificial layer with a roughened template surface includes depositing the sacrificial layer followed by a surface treatment to roughen the surface.

24. The method of claim 20, wherein depositing the conformal layer includes replicating the roughened surface to have a roughness of greater than about 2 nm rms.

25. The method of claim 20, wherein depositing the conformal layer includes depositing a material that is harder than a material defining the roughened surface.

26. The method of claim 20, wherein depositing the conformal layer includes depositing a dielectric material.

27. The method of claim 20, further including forming a self-assembled monolayer (SAM) formed over the conformal layer.

28. The method of claim 27, wherein the SAM is deposited by n-decyl-trichlorosilane.

29. The method of claim 27, wherein depositing the conformal layer and forming the SAM are conducted in-situ in a same deposition chamber.

30. The method of claim 20, wherein the conformal layer deposited by ALD has a thickness of about 2.5 nm to about 10 nm.

31. The method of claim 20, wherein the conformal layer deposited by ALD includes one or more of Al₂O₃, HfO₂, Ta₂O₅, SiO₂.

32. The method of claim 31, wherein depositing the conformal layer includes supplying alternate and sequential pulses of water and trimethyl aluminum to a substrate to form Al₂O₃.

33. The method of claim 20, wherein forming the sacrificial layer includes depositing molybdenum.

34. The method of claim 20, wherein forming the second electrode includes providing a surface facing the sacrificial layer with a roughness of between about 1.5 nm rms and about 6 nm rms.

35. The method of claim 20, wherein depositing the conformal layer includes replicating the roughened surface to have a roughness of about 1.5 nm to about 6 nm rms.

36. The method of claim 20, wherein the electromechanical systems device is an interferometric modulator.

37. An electromechanical systems device comprising:
a first electrode means;
a second, movable electrode means for actuating the device;
a cavity defined between the first electrode means and the second electrode means, wherein at least one of the first electrode means and the second electrode means has a roughened surface facing the cavity; and
means for reducing stiction covering surfaces of the first electrode means and the second electrode means that face the cavity, including over the roughened surface.

38. The apparatus of claim 37, wherein the means for reducing stiction includes a conformal dielectric layer.

39. The apparatus of claim 38, wherein the conformal dielectric layer has a surface having a roughness of from about 1.5 nm to about 6 nm rms.

40. The apparatus of claim 38, wherein the means for reducing stiction further includes a self-assembled monolayer (SAM) formed over the conformal dielectric layer.

41. The apparatus of claim 40, wherein the SAM is formed from n-decyl-trichlorosilane.

42. The apparatus of claim 38, wherein the conformal dielectric layer includes one or more of Al₂O₃, HfO₂, Ta₂O₅, SiO₂.

43. The apparatus of claim 38, wherein the conformal dielectric layer is deposited by ALD and has a thickness of about 2.5 nm to about 10 nm.

44. The apparatus of claim 37, wherein the conformal dielectric layer is Al₂O₃.

45. The apparatus of claim 38, wherein the roughened surface is defined by the conformal dielectric layer between the first electrode means and the cavity.

46. The apparatus of claim 37, wherein the first electrode means is a stationary electrode.
